(19) United States
(12) Patent Application Publication
(10) Pub. No.: US 2009/0323746 A1
(43) Pub. Date: Dec. 31, 2009

(54) Nitride Semiconductor Laser and Method for Fabricating Same

(76) Inventors: Susumu Ohmi, Hiroshima (JP); Takeshi Kamikawa, Hiroshima (JP)

Correspondence Address: HARNESS, DICKEY & PIERCE, P.L.C., P.O. BOX 8910, RESTON, VA, 20195, US

(21) Appl. No.: 11/922,137

(22) PCT Filed: Apr. 12, 2006
(86) PCT No.: PCT/JP06/07771

§ 371 Date: Dec. 13, 2007

(30) Foreign Application Priority Data
Jun. 16, 2005 (JP) 2005-175906

(51) Int. Cl. H01S 5/22; H01S 5/323; H01S 5/343; H01S 5/00; H01L 21/18; H01L 33/00

(52) U.S. Cl. 372/43.01; 438/31; 257/E33.023; 257/E21.085

(57) ABSTRACT

In one embodiment of the present invention, in a method of fabricating a nitride semiconductor laser device, after an insulating film is formed on a layered nitride semiconductor portion on a substrate, a resist mask is formed on the insulating film, such that the insulating film is exposed near a position where an exit-side cleaved facet and a reflection-side cleaved facet are formed. The insulating film near a position where the exit-side cleaved facet and the reflection-side cleaved facet are formed is then removed, and, after the resist mask is removed, cleavage is performed. As a result, even if the substrate and the layered nitride semiconductor portion are cleaved at a position where the exit-side cleaved facet and the reflection-side cleaved facet are formed, the insulating film is not broken. This helps prevent fragments produced from the insulating film from being adhered to the exit-side cleaved facet and to the reflection-side cleaved facet.

### TECHNICAL FIELD

The present invention relates to nitride semiconductor laser devices that can be fabricated at an increased yield rate and can offer a highly reliable laser facet, and to a method of fabricating such nitride semiconductor laser devices.

### BACKGROUND ART

In a nitride semiconductor laser device having a waveguide in the form of a ridge stripe, an electrode is generally formed on a layered nitride semiconductor portion on which a waveguide and an insulating protective film are formed, the waveguide being formed on the upper face of the layered nitride semiconductor portion formed on the substrate, and the insulating protective film having an opening on the upper face of the waveguide. An example of the nitride semiconductor laser device structured as described above is seen in Patent Document 1 shown in FIG. 23.

FIG. 23 is a sectional view of a nitride semiconductor laser device 100 taken along a direction perpendicular to a waveguide region 115 in the form of a raised stripe (a ridge stripe), that is, a direction parallel to a laser facet. The nitride semiconductor laser device 100 has the following layers formed one on top of another on a nitride semiconductor substrate 106 exhibiting n-type conductivity: an n-type crack prevention layer 107, an n-type clad layer 108, an optical guide layer 109, an active layer 110, a p-type cap layer 111, an optical guide layer 112, a p-type clad layer 113, and a p-type contact layer 114. Part of these layers and the nitride semiconductor substrate 106 is etched to form a waveguide region 115 in the form of a raised stripe. On the upper face of the nitride semiconductor substrate 106 and on side faces of the waveguide region 115 is formed a first protective film 104 having an opening on the upper face of the waveguide region 115 and serving as an insulating protective film. The waveguide region 115 and a part around it are coated with a p-type electrode 101. A second protective film 105 is formed on the upper face of the nitride semiconductor substrate 106 except where the p-type electrode 101 is formed, and a pad electrode 102 is formed on the p-type electrode 101 and the second protective film 105.

Patent Document 1: JP-A-H11-330610 (page 5, FIG. 1)

### DISCLOSURE OF THE INVENTION

### Problems to be Solved by the Invention

In this conventional nitride semiconductor laser device 100, the nitride semiconductor substrate 106 is cleaved to form a laser facet. At the time of this cleavage, the first protective film 104 and the second protective film 105 are also broken, producing fine fragments because of their hardness and brittleness. That is, the first protective film 104 and the second protective film 105 are dust producing sources. If these fragments are adhered to the laser light-emitting point of the laser facet or a part around it, they cause abnormalities in the light-emitting characteristics of the nitride semiconductor laser device 100. This makes the nitride semiconductor laser device 100 defective, lowering the yield of the device.

Even if these fragments are adhered to a spot other than the laser light-emitting point and a part around it, there is a possibility that a coating film formed on the cleaved facet begins to fall off from where these fragments are adhered. This disadvantageously reduces the long-term reliability of the nitride semiconductor laser device 100.

On the other hand, in a gallium nitride semiconductor laser device, the following problem arises. Since the gallium nitride semiconductor laser device operates at a relatively short oscillation wavelength of around 405 nm, when it is driven, the coating film formed on the cleaved facet is activated by the emitted light, and the reactivity thereof is increased. Here, suppose that SiO₂ is used as an insulating protective film and the coating film formed on the cleaved facet contains Al or Hf. Then, Si in the insulating protective film and Al or Hf in the coating film form a eutectic. Thus, when the temperature of the laser facet increases to 100° C. or higher for example as a result of this nitride semiconductor laser device being continuously driven, a eutectic is formed in the coating film. As a result, the reflectivity of the coating film may be greatly deviated from the design value, resulting in undesirable variations in the laser driving characteristics.

Therefore, an object of the present invention is to provide nitride semiconductor laser devices that prevent an insulating protective film from producing fragments at the time of the cleavage of a nitride semiconductor substrate, that can be fabricated at a good yield rate, and that offer a highly reliable laser facet, and to provide a method of fabricating such nitride semiconductor laser devices.

### Means for Solving the Problem

To achieve the above object, according to one aspect of the present invention, in a nitride semiconductor laser device provided with: a substrate; a layered nitride semiconductor portion having a plurality of nitride semiconductor layers formed one on top of another on the substrate, the layered nitride semiconductor portion having a waveguide in the form of a ridge stripe; an insulating layer formed on the layered nitride semiconductor portion so as to have an opening on the waveguide; and a first electrode formed on the waveguide and the insulating layer, no insulating layer is formed on part of the layered nitride semiconductor portion at least around ends of the waveguide along a length thereof, such that the layered nitride semiconductor portion is exposed in that part.

Preferably, the semiconductor laser device structured as described above is further provided with a second electrode formed between the waveguide and the first electrode. The second electrode is formed all over an upper face of the waveguide.

Preferably, in the semiconductor laser device structured as described above, the length of an area on the layered nitride semiconductor portion, the area in which no insulating layer is formed, in a direction parallel to the longer sides of the waveguide is 2 μm or more but 20 μm or less.

Preferably, in the semiconductor laser device structured as described above, a coating film is formed on at least one facet of the substrate and the layered nitride semiconductor portion perpendicular to the longer sides of the waveguide so as to lie on the top of the layered nitride semiconductor portion but not to make contact with the insulating layer.

According to another aspect of the present invention, a method of fabricating a nitride semiconductor laser device is provided with: a first step of forming a layered nitride semiconductor portion by forming a plurality of nitride semiconductor layers one of top of another on a substrate; a second step of forming a first resist mask in the form of a stripe on an upper face of the layered nitride semiconductor portion formed in the first step; a third step of forming a waveguide in the form of a ridge stripe in the layered nitride semiconductor portion by etching an upper portion of the layered nitride semiconductor portion, the upper portion not being coated with the first resist mask formed in the second step; a fourth step of forming an insulating layer on the layered nitride semiconductor portion including the first resist mask, the layered nitride semiconductor portion being etched in the third step; a fifth step of forming an opening in the insulating layer by removing the insulating layer formed on the first resist mask in the fourth step and the first resist mask; a sixth step of forming a first electrode on the insulating layer having the opening formed in the fifth step and on the layered nitride semiconductor portion; a seventh step of forming a second resist mask on the insulating layer and on the electrode formed in the sixth step except around a cleavage position perpendicular to the longer sides of the waveguide; an eighth step of removing a portion of the insulating layer, the portion not being coated with the second resist mask formed in the seventh step; and a ninth step of removing the second resist mask after removing the insulating layer in the eighth step.

Preferably, in the nitride semiconductor laser device fabrication method, in the second step, after a second electrode is formed on the upper face of the layered nitride semiconductor portion formed in the first step, the first resist mask in the form of a stripe is formed on an upper face of the second electrode; in the third step, after a portion of the second electrode formed in the second step, the portion not being coated with the first resist mask, is removed, the waveguide in the form of a ridge stripe is formed in the layered nitride semiconductor portion by etching a portion of a surface of the layered nitride semiconductor portion, the portion not being in contact with the second electrode; in the sixth step, the first electrode is formed on the insulating layer and on the second electrode; and in the seventh step, the second resist mask is formed on the insulating layer, on the first electrode, and on the second electrode except around the cleavage position.

Preferably, the semiconductor laser device fabrication method is further provided with: a tenth step of performing cleavage at the cleavage position after removing the second resist mask in the ninth step; and an eleventh step of forming a coating film on at least one cleaved facet formed by cleavage in the tenth step in such a way that the coating film does not make contact with the insulating layer.

### BRIEF DESCRIPTION OF DRAWINGS

FIG. 1 A partial perspective view showing a nitride semiconductor laser device according to a first embodiment.

FIG. 2 A partial front view showing the layered nitride semiconductor portion according to the first embodiment and a part around it.

FIG. 3 A partial sectional view showing a method of fabricating the nitride semiconductor laser device according to the first embodiment.

FIG. 4 A partial sectional view showing the method of fabricating the nitride semiconductor laser device according to the first embodiment.

FIG. 5 A partial sectional view showing the method of fabricating the nitride semiconductor laser device according to the first embodiment.

FIG. 6 A partial sectional view showing the method of fabricating the nitride semiconductor laser device according to the first embodiment.

FIG. 7 A partial sectional view showing the method of fabricating the nitride semiconductor laser device according to the first embodiment.

FIG. 8 A partial sectional view showing the method of fabricating the nitride semiconductor laser device according to the first embodiment.

FIG. 9 A partial perspective view showing the method of fabricating the nitride semiconductor laser device according to the first embodiment.

FIG. 10 A partial perspective view showing the method of fabricating the nitride semiconductor laser device according to the first embodiment.

FIG. 11 A partial perspective view showing a nitride semiconductor laser device according to a second embodiment.

FIG. 12 A partial sectional view showing a method of fabricating the nitride semiconductor laser according to the second embodiment.

FIG. 13 A partial sectional view showing the method of fabricating the nitride semiconductor laser according to the second embodiment.

FIG. 14 A partial sectional view showing the method of fabricating the nitride semiconductor laser according to the second embodiment.

FIG. 15 A partial sectional view showing the method of fabricating the nitride semiconductor laser according to the second embodiment.

FIG. 16 A partial sectional view showing the method of fabricating the nitride semiconductor laser according to the second embodiment.

FIG. 17 A partial sectional view showing the method of fabricating the nitride semiconductor laser according to the second embodiment.

FIG. 18 A partial sectional view showing the method of fabricating the nitride semiconductor laser according to the second embodiment.

FIG. 19 A partial perspective view showing the method of fabricating the nitride semiconductor laser according to the second embodiment.

FIG. 20 A partial perspective view showing the method of fabricating the nitride semiconductor laser according to the second embodiment.

FIG. 21 A partial perspective view showing the method of fabricating the nitride semiconductor laser according to the second embodiment.

FIG. 22 A partial perspective view showing a nitride semiconductor laser device according to a third embodiment.

FIG. 23 A schematic sectional view showing a conventional nitride semiconductor laser device.

### LIST OF REFERENCE SYMBOLS

1 Nitride semiconductor laser device
10 N-type GaN substrate
11 Layered nitride semiconductor portion
12 Waveguide
15 Cleavage position
21 Insulating film
21a Opening
31 P-side electrode
33 Contact electrode
34 Pad electrode
51 Front coating film
52 Back coating film
61 Gap
62 Gap

### BEST MODE FOR CARRYING OUT THE INVENTION

### First Embodiment

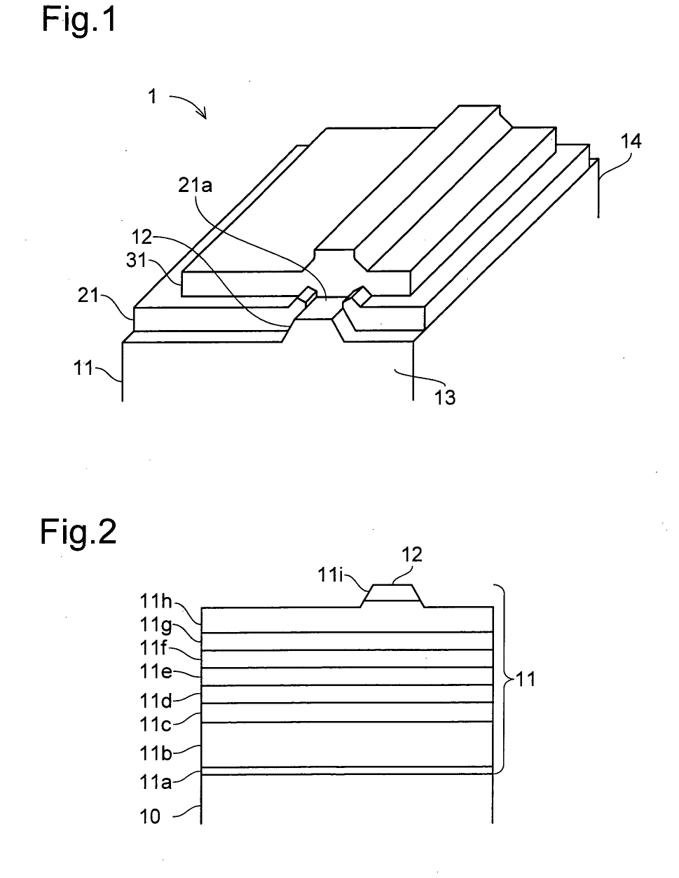

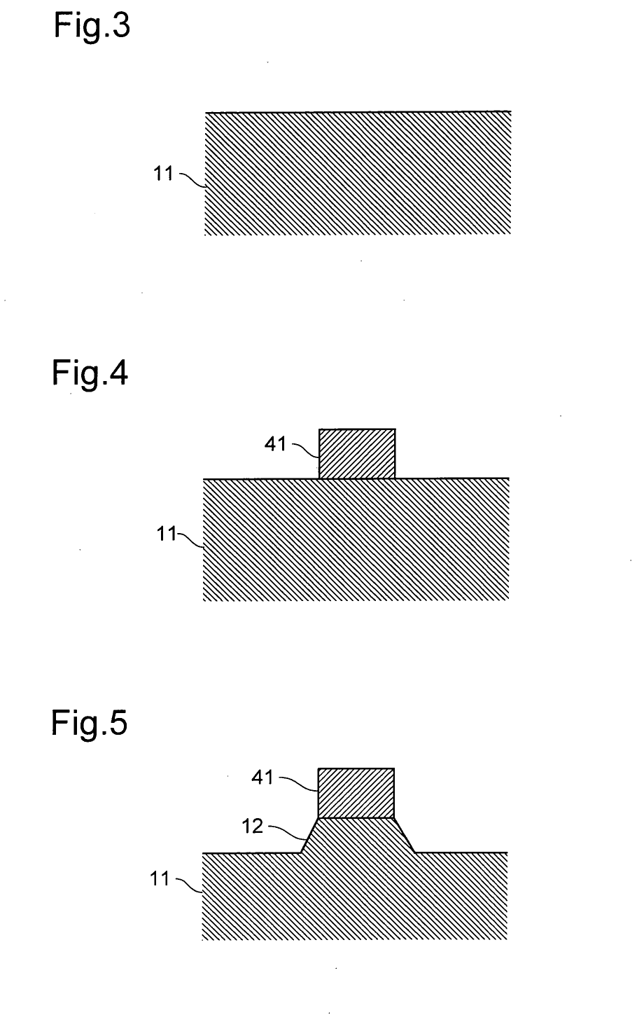

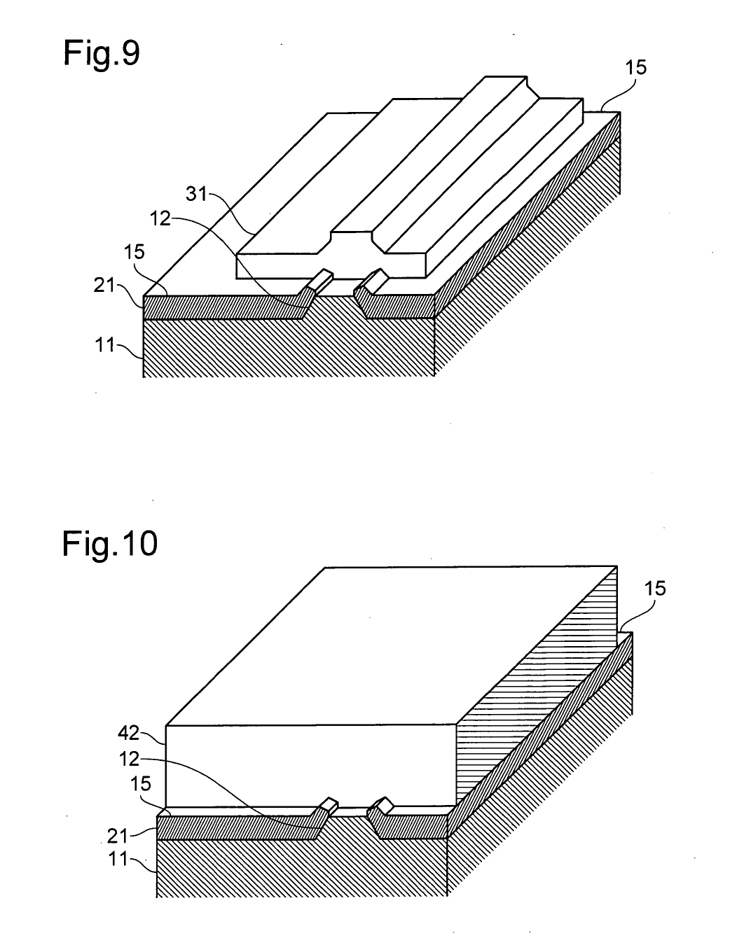

Hereinafter, a first embodiment of the present invention will be described with reference to FIGS. 1 to 10. FIG. 1 is a partial perspective view showing a nitride semiconductor laser device according to a first embodiment. FIG. 2 is a partial front view showing the layered nitride semiconductor portion according to the first embodiment and a part around it. FIGS. 3 to 8 are partial sectional views showing a method of fabricating the nitride semiconductor laser device according to the first embodiment, and FIGS. 9 and 10 are partial perspective views thereof.

As shown in FIG. 1, the nitride semiconductor laser device 1 according to the first embodiment has a layered nitride semiconductor portion 11 formed on an n-type GaN substrate (not shown). As shown in FIG. 2, the layered nitride semiconductor portion 11 has the following layers formed one on top of another in the order mentioned and grown at a low temperature on an n-type GaN substrate 10: a Si-doped GaN buffer layer 11a, an n-type GaN layer 11b, an n-type AlGaN clad layer 11c, an n-type GaN optical waveguide layer 11d, an InGaN multiple quantum well active layer 11e, a p-type AlGaN cap layer 11f, a p-type GaN optical waveguide layer 11g, a p-type AlGaN clad layer 11h, and a P-type GaN contact layer 11i.

The layered nitride semiconductor portion 11 has a waveguide 12 in the form of a 2 μm-wide ridge stripe formed by removing an upper portion of the p-type AlGaN clad layer 11h and part of the P-type GaN contact layer 11i. On the layered nitride semiconductor portion 11 is formed an insulating film 21 that is made of SiO₂ having a thickness of 3500 Å and that has an opening 21a in an area corresponding to the upper face of the waveguide 12. On the insulating film 21 and on the upper face of the waveguide 12, Pd having a thickness of 500 Å and Au having a thickness of 6000 Å are formed one on top of another in the order mentioned to form a p-side electrode 31, which forms ohmic contact with the upper face of the waveguide 12 via the opening 21a of the insulating film 21. The insulating film 21 is located about 10 μm away from an exit-side cleaved facet 13 and a reflection-side cleaved facet 14 that are formed by the cleavage. The upper face of the layered nitride semiconductor portion 11 is exposed within a distance of 10 μm from the exit-side cleaved facet 13 and the reflection-side cleaved facet 14.

Next, a method of fabricating the nitride semiconductor laser device 1 according to the first embodiment will be described with reference to FIGS. 3 to 10.

First, as shown in FIG. 3, the layered nitride semiconductor portion 11 is formed on an n-type GaN substrate (not shown) by epitaxial growth techniques such as metal organic chemical vapor deposition (MOCVD) or molecular beam epitaxy (MBE).

Next, as shown in FIG. 4, on the surface of the layered nitride semiconductor portion 11, a first resist mask 41 in the form of a 2 μm-wide stripe is formed. Then, as shown in FIG. 5, the layered nitride semiconductor portion 11 masked by the first resist mask 41 is etched from the topmost surface thereof halfway through the p-type AlGaN clad layer 11h by reactive ion etching, so as to form the waveguide 12 (see FIG. 2). During this process, used as a process gas is, for example, chlorine gas Cl₂ or chlorine-based gas such as SiCl₄ or BCl₃.

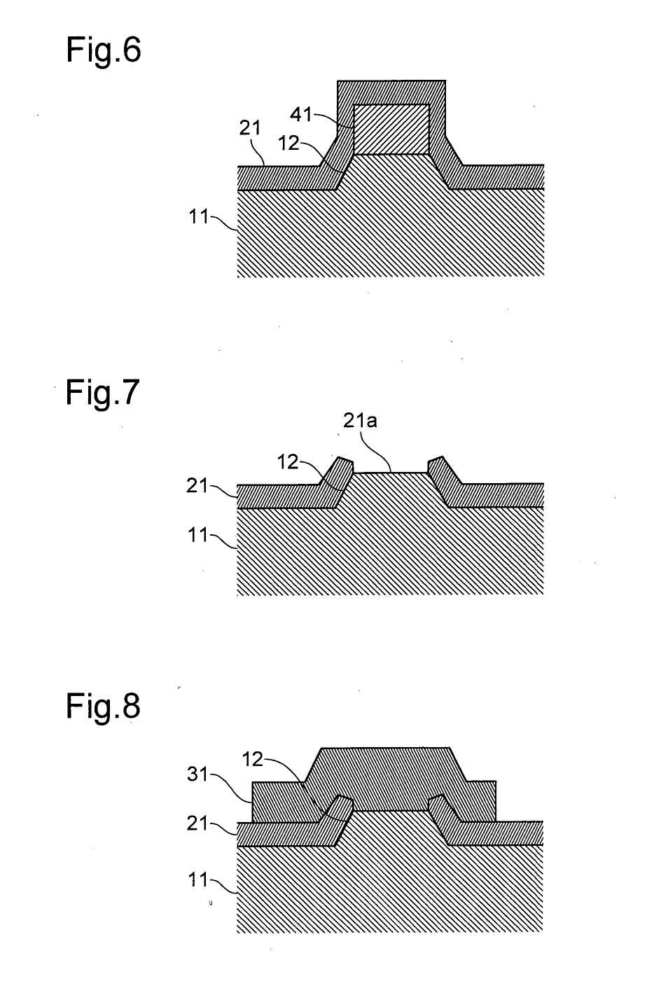

Next, as shown in FIG. 6, the insulating film 21 made of SiO₂ having a thickness of 3500 Å is formed all over the upper face of the layered nitride semiconductor portion 11 including the first resist mask 41 by the electron beam evaporation technique. Then, as shown in FIG. 7, the insulating film 21 formed on the first resist mask 41 and the first resist mask 41 are removed by a liftoff process, thereby forming the opening 21a in the insulating film 21. Next, as shown in FIG. 8 and FIG. 9 that is a perspective view of FIG. 8, on the upper face of the insulating film 21 and the waveguide 12, Pd having a thickness of 500 Å and Au having a thickness of 6000 Å are formed one on top of another in the order mentioned to form a p-side electrode 31. At this point, the p-side electrode 31 is formed in such a way that it is located away from positions where laser facets are formed, namely the cleavage positions 15.

Next, as shown in FIG. 10, a second resist mask 42 is formed on the insulating film 21 in such a way as to entirely cover the p-side electrode 31. At this point, the second resist mask 42 is formed in such a way that both the exit-side and reflection-side faces thereof are located 10 μm away from the cleavage positions 15. Then, a portion of the insulating film 21, the portion where the insulating film 21 is exposed from the second resist mask 42, is etched by reactive ion etching until the layered nitride semiconductor portion 11 is exposed. During this process, used as a process gas is, for example, CHF₃ or CF₄. Finally, the second resist mask 42 is removed by an organic solvent, and cleavage is performed so as to form the exit-side cleaved facet 13 and the reflection-side cleaved facet 14. In this way, the nitride semiconductor laser device 1 having the structure as shown in FIG. 1 is obtained.

With this fabrication method, the insulating film 21 is not located on the cleavage positions in the yet-to-be-cleaved nitride semiconductor laser device 1. This eliminates the possibility of fragments being produced from the insulating film 21 made of SiO₂ when cleavage is performed to form the exit-side cleaved facet 13 and the reflection-side cleaved facet 14. As a result, no foreign substance is produced from the insulating film 21 and adhered to the exit-side cleaved facet 13 and the reflection-side cleaved facet 14. This helps greatly improve the yield of the nitride semiconductor laser device 1 in terms of light emission characteristics.

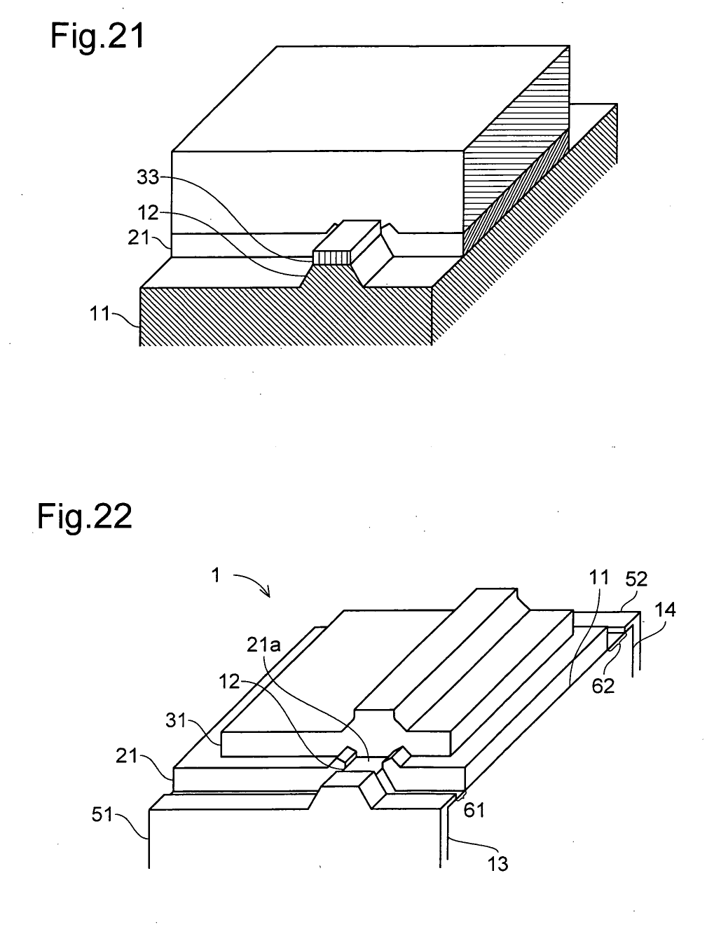

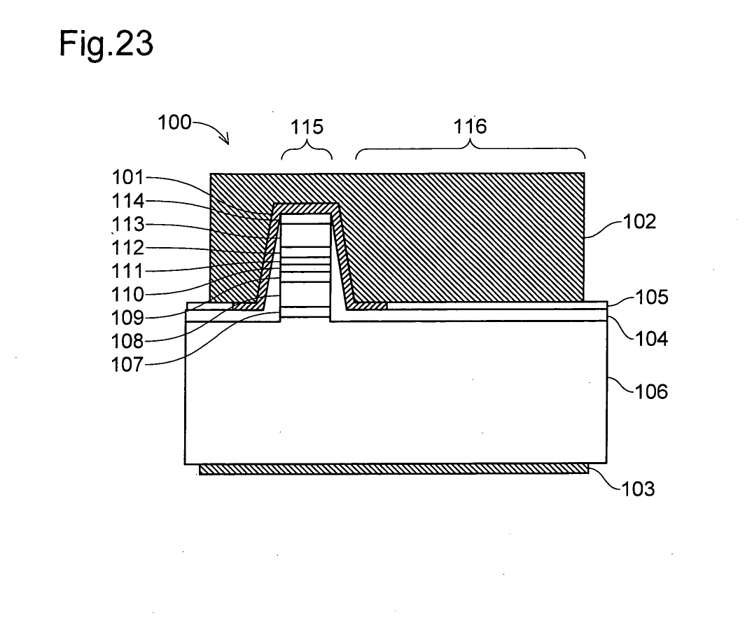

Incidentally, a long-term reliability test was conducted to a product obtained by applying a coating to the exit-side cleaved facet 13 and to the reflection-side cleaved facet 14 of the nitride semiconductor laser device 1 shown in FIG. 1, the product thus obtained being shown in FIG. 21, which will be described below. The test revealed the following results. In the nitride semiconductor laser device fabricated by the conventional fabrication method, the facet coating occasionally begins to fall off from part of the cleaved facet where a foreign substance is adhered. Such falling of the facet coating was dramatically reduced, indicating that the reliability is improved.

The first embodiment deals with a case where the insulating film 21 is located 10 μm away from the exit-side cleaved facet 13 and the reflection-side cleaved facet 14; it is preferable that the insulating film 21 be located at a distance of 2 μm or more but 20 μm or less from the cleaved facets.

If that distance is less than 2 μm, the following problem arises. At the time of cleavage, the exit-side cleaved facet 13 and the reflection-side cleaved facet 14 are distorted due to voids or the like in the layered nitride semiconductor portion 11, and the cleaved facets make contact with the insulating film 21. This may cause the breakage of the insulating film 21, producing fragments thereof.

On the other hand, if that distance is greater than 20 μm, there is a high possibility that the linearity of the current-optical output characteristics of the nitride semiconductor laser device 1 is distorted. The reason is as follows. In the structure shown in FIG. 1, since no p-side electrode 31 is provided in a portion from which the insulating film 21 is removed, no current is applied to the waveguide 12 formed in that portion. The influence of that portion on the current-optical output characteristics becomes too significant to be ignored.

### Second Embodiment

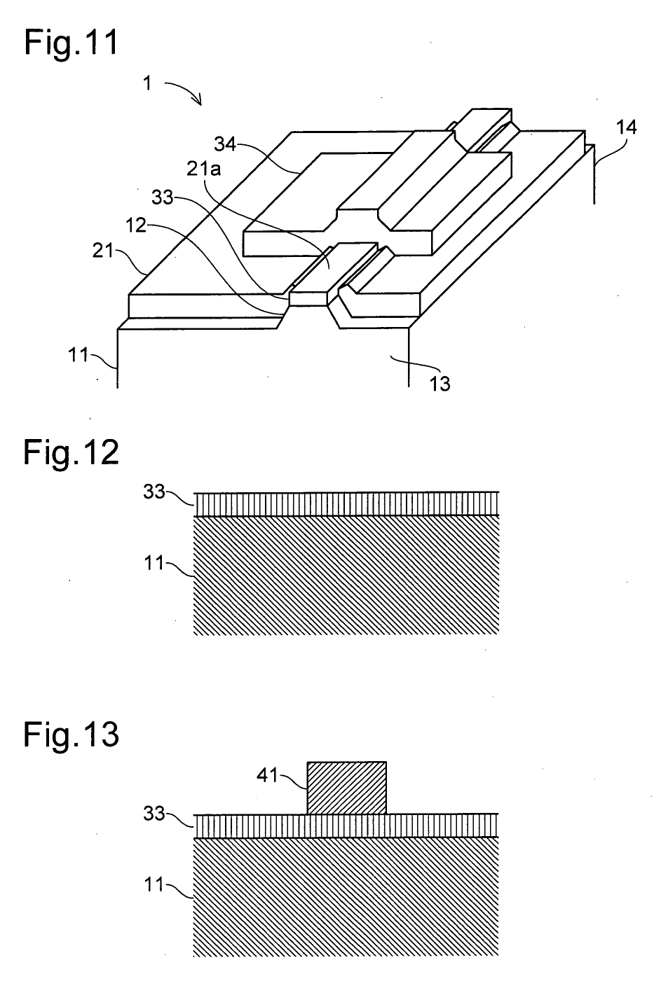

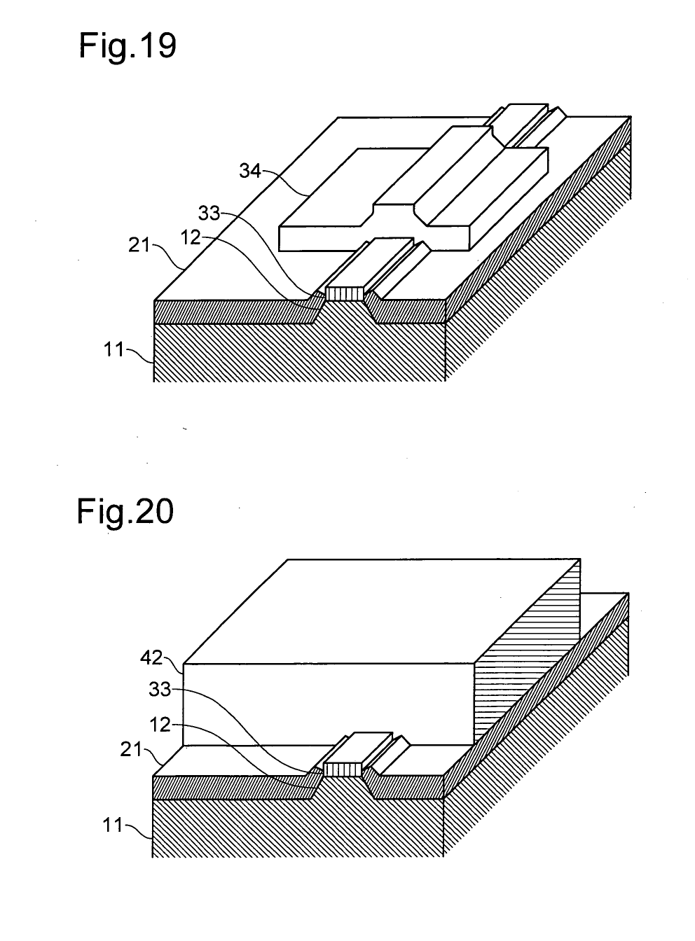

A second embodiment of the present invention will be described with reference to FIGS. 11 to 21. FIG. 11 is a partial perspective view showing a nitride semiconductor laser device according to the second embodiment. FIGS. 12 to 18 are partial sectional views showing a method of fabricating the nitride semiconductor laser according to the second embodiment, and FIGS. 19 to 21 are partial perspective views thereof. The second embodiment differs from the first embodiment only in that a contact electrode is formed on the waveguide, and a pad electrode is formed in place of the p-side electrode. In other respects, the second embodiment is the same as the first embodiment. Therefore, such components as find their substantially identical counterparts in the first embodiment are identified with the same reference characters.

As shown in FIG. 11, a nitride semiconductor laser device 1 according to the second embodiment has a layered nitride semiconductor portion 11 formed on an n-type GaN substrate (not shown). The structure of the layered nitride semiconductor portion 11 is the same as in the first embodiment shown in FIG. 2.

As is the case with the first embodiment, the layered nitride semiconductor portion 11 has a waveguide 12 formed therein, and an insulating film 21 having an opening 21a in an area corresponding to the upper face of the waveguide 12 is formed on the layered nitride semiconductor portion 11. On the upper face of the waveguide 12, a contact electrode 33 made of Pd having a thickness of 500 Å is formed in such a way as to form ohmic contact with the upper face of the waveguide 12. On the insulating film 21 and the contact electrode 33 is formed a pad electrode 34 made of Au having a thickness of 6000 Å. The insulating film 21 is located 25 μm away from an exit-side cleaved facet 13 and a reflection-side cleaved facet 14 that are formed by the cleavage. The upper face of the layered nitride semiconductor portion 11 is exposed within a distance of 25 μm from the exit-side cleaved facet 13 and the reflection-side cleaved facet 14.

Next, a method of fabricating the nitride semiconductor laser device 1 according to the second embodiment will be described with reference to FIGS. 12 to 21.

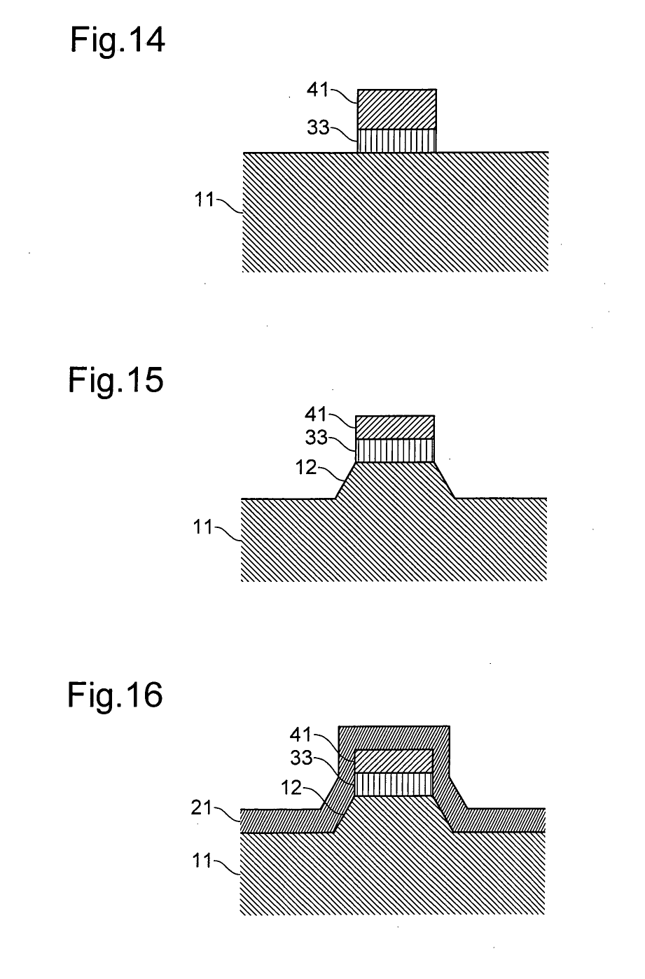

First, the layered nitride semiconductor portion 11 is formed on the n-type GaN substrate (not shown) in the same manner as in the first embodiment. Then, as shown in FIG. 12, the contact electrode 33 is formed on the surface of the layered nitride semiconductor portion 11, and, as shown in FIG. 13, a first resist mask 41 in the form of a 2 μm-wide stripe is then formed on the contact electrode 33. Then, as shown in FIG. 14, the contact electrode 33 masked by the first resist mask 41 is etched by reactive ion etching until the surface of the layered nitride semiconductor portion 11 is exposed. At this point, used as an etching gas is, for example, Ar or CHF₃. Next, as shown in FIG. 15, the layered nitride semiconductor portion 11 masked by the first resist mask 41 is etched from the topmost surface thereof halfway through the p-type AlGaN clad layer 11h by reactive ion etching, so as to form the waveguide 12. During this process, used as a process gas is, for example, chlorine gas Cl₂ or chlorine-based gas such as SiCl₄ or BCl₃.

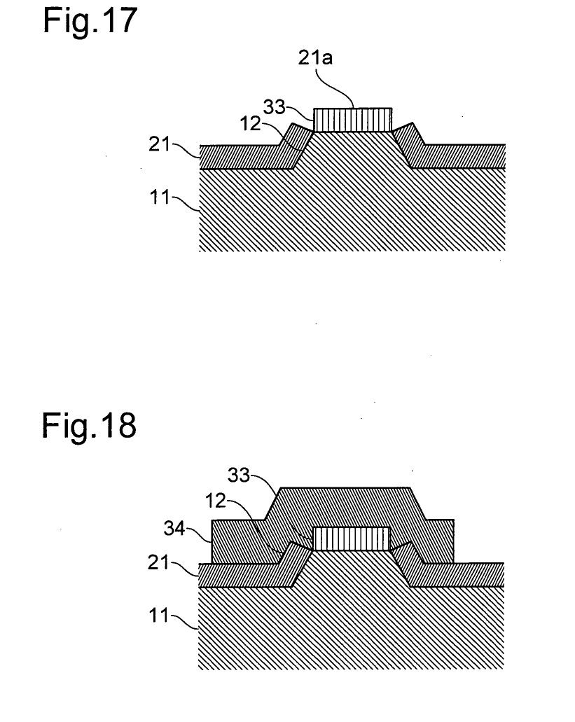

Next, as shown in FIG. 16, the insulating film 21 made of SiO₂ having a thickness of 3500 Å is formed all over the upper face of the layered nitride semiconductor portion 11 including the side faces of the first resist mask 41 and the contact electrode 33 by the electron beam evaporation technique. Then, the insulating film 21 formed on the first resist mask 41 and the first resist mask 41 are removed by a liftoff process, thereby forming the opening 21a in the insulating film 21. The product thus obtained is shown in FIG. 17.

Next, as shown in FIG. 18 and FIG. 19 that is a perspective view of FIG. 18, on the insulating film 21 and the contact electrode 33 is formed the pad electrode 34 made of Au having a thickness of 6000 Å. At this point, the pad electrode 34 is formed in such a way that it is located away from positions where laser facets are formed, namely cleavage positions 15.

Next, as shown in FIG. 20, a second resist mask 42 is formed on the insulating film 21 in such a way as to entirely cover the contact electrode 33 and the pad electrode 34. At this point, the second resist mask 42 is formed in such a way that both the exit-side and reflection-side faces thereof are located 25 μm away from the cleavage positions 15.

Then, as is the case with the first embodiment, a portion of the insulating film 21, the portion where the insulating film 21 is exposed from the second resist mask 42, is etched by reactive ion etching until the layered nitride semiconductor portion 11 is exposed. Finally, the second resist mask 42 is removed by an organic solvent, and cleavage is performed so as to form the exit-side cleaved facet 13 and the reflection-side cleaved facet 14. In this way, the nitride semiconductor laser device 1 having the structure as shown in FIG. 11 is obtained.

With this fabrication method, the nitride semiconductor laser device 1 according to the second embodiment has the following advantages. As is the case with the first embodiment, since the insulating film 21 is not located on the cleavage positions, there is no possibility of fragments being produced from the insulating film 21 made of SiO₂ when cleavage is performed to form the exit-side cleaved facet 13 and the reflection-side cleaved facet 14. As a result, no foreign substance is produced from the insulating film 21 and adhered to the exit-side cleaved facet 13 and the reflection-side cleaved facet 14. This helps greatly improve the yield of the nitride semiconductor laser device 1 in terms of light emission characteristics.

Unlike the first embodiment, since the contact electrode 33 reaches right above the laser facets, namely the exit-side cleaved facet 13 and the reflection-side cleaved facet 14, current is applied to the whole of the waveguide 12. As a result, unlike a case in which the waveguide 12 has an area where no electrode is provided, there is no possibility that the linearity of the current-optical output characteristics is distorted due to the applied current.

### Third Embodiment

A third embodiment of the present invention will be described with reference to FIG. 22. FIG. 22 is a partial perspective view showing a nitride semiconductor laser device according to the third embodiment of the invention. The third embodiment differs from the first embodiment only in that a coating film is applied to an exit-side cleaved facet 13 and to a reflection-side cleaved facet 14. In other respects, the third embodiment is the same as the first embodiment. Therefore, such components as find their substantially identical counterparts in the first embodiment are identified with the same reference characters.

As shown in FIG. 22, a nitride semiconductor laser device 1 according to the third embodiment has a waveguide 12 formed in a layered nitride semiconductor portion 11 having a structure shown in FIG. 2 as in the first embodiment, and an insulating film 21 that is made of SiO₂ and has an opening 21a in an area corresponding to the upper face of the waveguide 12 is formed on the layered nitride semiconductor portion 11. On the upper face of the insulating film 21 and the waveguide 12, Pd having a thickness of 500 Å and Au having a thickness of 6000 Å are formed one on top of another in the order mentioned to form a p-side electrode 31. The insulating film 21 is located 18 μm away from an exit-side cleaved facet 13 and a reflection-side cleaved facet 14 that are formed by the cleavage.

In the third embodiment, a front coating film 51 made of Al₂O₃ having a thickness of 70 Å is formed on the surface of the exit-side cleaved facet 13, and a back coating film 52 having a multiple-layered structure composed of nine layers of SiO₂ and TiO₂ alternately formed one of top of another is formed on the surface of the reflection-side cleaved facet 14. The front coating film 51 and the back coating film 52 cover part of the upper face of the layered nitride semiconductor portion 11 in such a way as to leave a gap 61 and a gap 62 between them and the insulating film 21, respectively.

In a case where a laser operates at a relatively short oscillation wavelength of around 405 nm, if the nitride semiconductor laser device 1 thus obtained is continuously driven, the front coating film 51 is activated by the emitted light, and the reactivity thereof is increased. Here, consider a case where the front coating film 51 and the insulating film 21 overlap each other with no gap 61 interposed between them. Then, if the temperatures of the laser facets, namely the exit-side cleaved facet 13 and the reflection-side cleaved facet 14 increase to 100° C. or higher for example as a result of the continuous driving, the front coating film 51 made of Al₂O₃ reacts with the insulating film 21 made of SiO₂ to form a eutectic of Al and Si in the front coating film 51. The eutectic thus formed may cause the reflectivity of the front coating film 51 to be greatly deviated from the design value, resulting in undesirable variations in the laser driving characteristics of the semiconductor laser device 10. This reduces the long-term reliability thereof. By contrast, in the third embodiment, since the front coating film 51 and the insulating film 21 are disposed with the gap 61 interposed between them, there is no possibility that a eutectic of Al and Si is formed in the front coating film 51. This helps greatly improve the long-term reliability.

This is the end of the descriptions of the first to third embodiments of the present invention. It is to be understood that the present invention is not limited in any way by the embodiments thereof described above.

Next, variations of the present invention will be described. The “nitride semiconductor” described in the present specification should be understood to denote any semiconductor in which Ga in gallium nitride (GaN) is partially substituted by other elements of III group, for example, GaₛAlₜIn₁₋ₛ₋ₜN (0≦s≦1, 0≦t<1, 0<s+t≦1), and to denote any semiconductor in which part of any component element is substituted by an impurity element, or a semiconductor to which other impurities are added.

The first and third embodiments described above deal with cases in which the p-side electrode 31 is composed of two layers of Pd having a thickness of 500 Å and Au having a thickness of 6000 Å, which are formed one on top of another in the order mentioned on the surface of the layered nitride semiconductor portion 11; however, the structure of the p-side electrode 31 may be otherwise, such as a structure in which Pd and Au are each substituted by Ni, Ti, or the like, or a structure in which, on Pd, Au, Ni, Ti, or the like, a different metal such as Au or Mo is formed. Furthermore, these layers may be of any other thickness than is specifically described in the first and third embodiments. In any of these cases, a similar nitride semiconductor laser device can be achieved by the fabrication method of the present invention.

The second embodiment deals with a case in which the contact electrode 33 is made of Pd and the pad electrode 34 is made of Au; however, the contact electrode 33 may be made of Ni, Ti, or the like, and the pad electrode 34 may be made of Mo or the like. Alternatively, both electrodes may have a structure in which a plurality of metals such as Pd, Au, Ni, Ti, and Mo are formed one on top of another. Furthermore, these layers may be of any other thickness than is specifically described in the second embodiment. In any of these cases, a similar nitride semiconductor laser device can be achieved by the fabrication method of the present invention.

The first to third embodiments described above deal with cases in which the insulating film 21 is made of SiO₂; however, the insulating film 21 may be made of any other inorganic dielectric such as TiO₂, SiO, Ta₂O₅, or SiN, or a nitride semiconductor such as AlGaN. Furthermore, the insulating film 21 may be of any other thickness than is specifically described in the embodiments. Moreover, the formation method of the insulating film 21 is not limited to the electron beam evaporation technique described in the embodiments; the insulating film 21 may be formed by any other method such as sputtering or plasma CVD.

The descriptions heretofore deal with cases in which all the insulating film 21 reaching right above the laser facets, namely the exit-side cleaved facet 13 and the reflection-side cleaved facet 14, is removed; however, all the insulating film 21 reaching right above the laser facets does not necessarily have to be removed unless fragments of the insulating film 21 produced at the time of cleavage are scattered to the facet of the waveguide 12, from which light is emitted, and a part around it. For example, the insulating film 21 may be removed only from the waveguide 12 and a part around it.

The third embodiment of the invention corresponds to the nitride semiconductor laser device of the first embodiment to which a facet coating is applied. By applying a facet coating to the nitride semiconductor laser device of the second embodiment, it is possible to achieve the same effects.

The first to third embodiments of the invention deal with cases in which reactive ion etching is used as a dry etching method However, similar etching can be performed by using instead reactive ion beam etching, inductively coupled plasma etching, ECR plasma etching, or the like, as long as a similar process gas is used.

The first to third embodiments of the invention deal with cases in which, when a portion of the insulating film 21, the portion where the insulating film 21 is exposed from the second resist mask 42, is etched by reactive ion etching, it is etched until the layered nitride semiconductor portion 11 is exposed. However, even if part of the layered nitride semiconductor portion 11 is also etched at the time, it is possible to achieve the same effects.

### INDUSTRIAL APPLICABILITY

According to the present invention, since no insulating protective film is formed on part of a layered nitride semiconductor portion at least around the ends of a waveguide along its length, there is no possibility that, when the layered nitride semiconductor portion is cleaved to form a facet, the insulating protective film is broken. This prevents fragments from being produced from the broken insulating protective film and causing a problem, making it possible to realize a nitride semiconductor laser device that can be fabricated at an increased yield rate.

According to the present invention, since a second electrode is formed all over the upper face of the waveguide, unlike a case in which the waveguide has an area where no electrode is provided, there is no possibility that the linearity of the current-optical output characteristics is distorted due to the applied current.

According to the present invention, since the length of an area on the layered nitride semiconductor portion, the area in which no insulating layer is formed, in a direction parallel to the longer sides of the waveguide is 2 μm or more but 20 μm or less, even if a cleaved facet is distorted at the time of cleavage, there is no possibility of the insulating film being broken and producing fragments. In addition, even when the second electrode is formed only under the insulating layer, the linearity of the current-optical output characteristics suffers less distortion.

According to the present invention, since the insulating protective film does not make contact with a coating film formed on the cleaved facet, even if SiO₂, for example, is used as the insulating protective film and the coating film contains Al or Hf that reacts with Si to form a eutectic, no eutectic is formed in the coating film. This helps prevent the reflectivity of the coating film from varying due to a eutectic.

1. A nitride semiconductor laser device comprising:
a substrate;
a layered nitride semiconductor portion having a plurality of nitride semiconductor layers formed one on top of another on the substrate, the layered nitride semiconductor portion having a waveguide in a form of a ridge stripe;
an insulating layer formed on the layered nitride semiconductor portion so as to have an opening on the waveguide; and
a first electrode formed on the waveguide and the insulating layer,
wherein no insulating layer is formed on part of the layered nitride semiconductor portion at least around ends of the waveguide along a length thereof, such that the layered nitride semiconductor portion is exposed in that part.

2. The nitride semiconductor laser device of claim 1, further comprising:
a second electrode formed between the waveguide and the first electrode,
wherein the second electrode is formed all over an upper face of the waveguide.

3. The nitride semiconductor laser device of claim 1, wherein
a length of an area on the layered nitride semiconductor portion, the area in which no insulating layer is formed, in a direction parallel to longer sides of the waveguide is 2 μm or more but 20 μm or less.

4. The nitride semiconductor laser device of claim 1,
wherein a coating film is formed on at least one facet of the substrate and the layered nitride semiconductor portion perpendicular to longer sides of the waveguide so as to lie on a top of the layered nitride semiconductor portion but not to make contact with the insulating layer.

5. A method of fabricating a nitride semiconductor laser device, comprising:
a first step of forming a layered nitride semiconductor portion by forming a plurality of nitride semiconductor layers one of top of another on a substrate;
a second step of forming a first resist mask in a form of a stripe on an upper face of the layered nitride semiconductor portion formed in the first step;
a third step of forming a waveguide in a form of a ridge stripe in the layered nitride semiconductor portion by etching an upper portion of the layered nitride semiconductor portion, the upper portion not being coated with the first resist mask formed in the second step;
a fourth step of forming an insulating layer on the layered nitride semiconductor portion including the first resist mask, the layered nitride semiconductor portion being etched in the third step;
a fifth step of forming an opening in the insulating layer by removing the insulating layer formed on the first resist mask in the fourth step and the first resist mask;
a sixth step of forming a first electrode on the insulating layer having the opening formed in the fifth step and on the layered nitride semiconductor portion;
a seventh step of forming a second resist mask on the insulating layer and on the electrode formed in the sixth step except around a cleavage position perpendicular to longer sides of the waveguide;
an eighth step of removing a portion of the insulating layer, the portion not being coated with the second resist mask formed in the seventh step; and
a ninth step of removing the second resist mask after removing the insulating layer in the eighth step.

6. The nitride semiconductor laser device fabrication method of claim 5,
wherein, in the second step, after a second electrode is formed on the upper face of the layered nitride semiconductor portion formed in the first step, the first resist mask in a form of a stripe is formed on an upper face of the second electrode,
wherein, in the third step, after a portion of the second electrode formed in the second step, the portion not being coated with the first resist mask, is removed, the waveguide in a form of a ridge stripe is formed in the layered nitride semiconductor portion by etching a portion of a surface of the layered nitride semiconductor portion, the portion not being in contact with the second electrode,
wherein, in the sixth step, the first electrode is formed on the insulating layer and on the second electrode,
wherein, in the seventh step, the second resist mask is formed on the insulating layer, on the first electrode, and on the second electrode except around the cleavage position.

7. The nitride semiconductor laser device fabrication method of claim 5, further comprising:
a tenth step of performing cleavage at the cleavage position after removing the second resist mask in the ninth step; and
an eleventh step of forming a coating film on at least one cleaved facet formed by cleavage in the tenth step in such a way that the coating film does not make contact with the insulating layer.

8. The nitride semiconductor laser device of claim 2,
wherein a coating film is formed on at least one facet of the substrate and the layered nitride semiconductor portion perpendicular to longer sides of the waveguide so as to lie on a top of the layered nitride semiconductor portion but not to make contact with the insulating layer.

9. The nitride semiconductor laser device of claim 3,
wherein a coating film is formed on at least one facet of the substrate and the layered nitride semiconductor portion perpendicular to longer sides of the waveguide so as to lie on a top of the layered nitride semiconductor portion but not to make contact with the insulating layer.

10. The nitride semiconductor laser device fabrication method of claim 6, further comprising:
a tenth step of performing cleavage at the cleavage position after removing the second resist mask in the ninth step; and
an eleventh step of forming a coating film on at least one cleaved facet formed by cleavage in the tenth step in such a way that the coating film does not make contact with the insulating layer.
